(19) United States
(12) Patent Application Publication
(10) Pub. No.: US 2023/0050925 A1
(43) Pub. Date: Feb. 16, 2023

(54) METHOD OF MANUFACTURING SEMICONDUCTOR STRUCTURE AND SEMICONDUCTOR STRUCTURE

(71) Applicant: CHANGXIN MEMORY TECHNOLOGIES, INC., Hefei City (CN)

(72) Inventors: Xinru HAN, Hefei City (CN); Yang CHEN, Hefei City (CN); Shiran ZHANG, Hefei City (CN)

(21) Appl. No.: 17/647,740

(22) Filed: Jan. 12, 2022

Related U.S. Application Data
(63) Continuation of application No. PCT/CN2021/116946, filed on Sep. 7, 2021.

(30) Foreign Application Priority Data
Aug. 12, 2021 (CN) 202110926564.8

(51) Int. Cl. H01L 21/8234; H01L 21/8238; H01L 21/768; H01L 29/66

(52) U.S. Cl. CPC H01L 21/82345; H01L 21/823481; H01L 21/823842; H01L 21/76816; H01L 29/66545

(57) ABSTRACT

A method of manufacturing a semiconductor structure and a semiconductor structure are disclosed. The method of manufacturing a semiconductor structure includes: providing a substrate; forming multiple support structures on the substrate, where the multiple support structures are arranged at intervals along a first direction, and a gate trench is formed between every two adjacent support structures; forming a gate structure in the gate trench; and removing a part of each of the support structures, such that each of retained support structures forms two isolation sidewalls spaced apart, the two isolation sidewalls are arranged on opposite sidewalls of the adjacent gate structures respectively, and a filling region is formed by the two isolation sidewalls.

### CROSS-REFERENCE TO RELATED APPLICATIONS

This is a continuation of International Patent Application No. PCT/CN2021/116946, filed on Sep. 7, 2021, which claims the priority to Chinese Patent Application No. 202110926564.8, titled “METHOD OF MANUFACTURING SEMICONDUCTOR STRUCTURE AND SEMICONDUCTOR STRUCTURE” and filed on Aug. 12, 2021. The entire contents of International Patent Application No. PCT/CN2021/116946 and Chinese Patent Application No. 202110926564.8 are incorporated herein by reference.

### TECHNICAL FIELD

The present disclosure relates to, but is not limited to, a method of manufacturing a semiconductor structure and a semiconductor structure.

### BACKGROUND

A dynamic random access memory (DRAM) has advantages of a small volume, high integration, and low power consumption, and is faster than read-only memory (ROM). With the continuous development of the semiconductor industry and integrated circuit device technology, optimization of the profile in the semiconductor structure can effectively improve the product yield.

The existing process of a gate structure is prone to the necking phenomenon on sidewalls of the gate structure, which greatly reduces the performance of the semiconductor structure and thus seriously affects the product yield.

### SUMMARY

An overview of the subject matter detailed in the present disclosure is provided below.

The present disclosure provides a method of manufacturing a semiconductor structure and a semiconductor structure.

According to a first aspect, the embodiments of the present disclosure provide a method of manufacturing a semiconductor structure. The method of manufacturing a semiconductor structure includes:

providing a substrate;

forming multiple support structures on the substrate, where the multiple support structures are arranged at intervals along a first direction, and a gate trench is formed between every two adjacent support structures;

forming a gate structure in the gate trench, where a top surface of the gate structure is flush with a top surface of each of the support structures; and

removing a part of each of the support structures, such that each of the retained support structures forms two isolation sidewalls spaced apart, the two isolation sidewalls are arranged on opposite sidewalls of the adjacent gate structures respectively, and a filling region is formed by the two isolation sidewalls.

According to a second aspect, the embodiments of the present disclosure provide a semiconductor structure. The semiconductor structure includes:

a substrate, and gate structures arranged at intervals on the substrate, where isolation sidewalls are arranged on opposite sidewalls of every two adjacent gate structures;

a filling region is formed by two opposite isolation sidewalls spaced apart; and

a top surface of each of the gate structures is flush with a top surface of each of the isolation sidewalls.

### BRIEF DESCRIPTION OF THE DRAWINGS

To describe the technical solutions in the embodiments of the present disclosure or in the prior art more clearly, the following briefly describes the accompanying drawings required for describing the embodiments or the prior art. Apparently, the accompanying drawings in the following description show some embodiments of the present disclosure, and a person of ordinary skill in the art may still derive other drawings from these accompanying drawings without creative efforts.

FIG. 1 is a flowchart of a method of manufacturing a semiconductor structure according to an exemplary embodiment.

FIG. 2 is a schematic diagram of a substrate in a method of manufacturing a semiconductor structure according to an exemplary embodiment.

FIG. 3 is a schematic diagram of forming a first groove in a method of manufacturing a semiconductor structure according to an exemplary embodiment.

FIG. 4 is a schematic diagram of forming an initial sidewall protective layer in a method of manufacturing a semiconductor structure according to an exemplary embodiment.

FIG. 5 is a schematic diagram of forming a sidewall protective layer and a second groove in a method of manufacturing a semiconductor structure according to an exemplary embodiment.

FIG. 6 is a schematic diagram of forming a lightly-doped region in a method of manufacturing a semiconductor structure according to an exemplary embodiment.

FIG. 7 is a schematic diagram of forming a first initial oxide layer in a method of manufacturing a semiconductor structure according to an exemplary embodiment.

FIG. 8 is a schematic diagram of forming a first oxide layer and a third groove in a method of manufacturing a semiconductor structure according to an exemplary embodiment.

FIG. 9 is a schematic diagram of forming a source-drain region in the method of manufacturing a semiconductor structure according to an exemplary embodiment.

FIG. 10 is a schematic diagram of forming a second initial sacrificial layer in a method of manufacturing a semiconductor structure according to an exemplary embodiment.

FIG. 11 is a schematic diagram of forming a second sacrificial layer in a method of manufacturing a semiconductor structure according to an exemplary embodiment.

FIG. 12 is a schematic diagram of forming gate trenches and support structures in a method of manufacturing a semiconductor structure according to an exemplary embodiment.

FIG. 13 is a schematic diagram of forming an initial polysilicon layer in a method of manufacturing a semiconductor structure according to an exemplary embodiment.

FIG. 14 is a schematic diagram of forming a polysilicon layer in a method of manufacturing a semiconductor structure according to an exemplary embodiment.

FIG. 15 is a schematic diagram of forming an initial conductive layer in a method of manufacturing a semiconductor structure according to an exemplary embodiment.

FIG. 16 is a schematic diagram of forming a conductive layer in a method of manufacturing a semiconductor structure according to an exemplary embodiment.

FIG. 17 is a schematic diagram of forming an initial isolation layer in a method of manufacturing a semiconductor structure according to an exemplary embodiment.

FIG. 18 is a schematic diagram of forming an isolation layer and a gate structure in a method of manufacturing a semiconductor structure according to an exemplary embodiment.

FIG. 19 is a schematic diagram of forming a filling region in a method of manufacturing a semiconductor structure according to an exemplary embodiment.

FIG. 20 is a schematic diagram of forming a first photoresist layer in a method of manufacturing a semiconductor structure according to an exemplary embodiment.

FIG. 21 is a flowchart of a method of manufacturing a semiconductor structure according to an exemplary embodiment.

### DETAILED DESCRIPTION

To make the objectives, technical solutions, and advantages of the embodiments of the present disclosure clearer, the following clearly and completely describes the technical solutions in the embodiments of the present disclosure with reference to the accompanying drawings in the embodiments of the present disclosure. Apparently, the described embodiments are some but not all of the embodiments of the present disclosure. All other embodiments obtained by those skilled in the art based on the embodiments of the present disclosure without creative efforts should fall within the protection scope of the present disclosure. It should be noted that without conflict, the embodiments in the present disclosure and features in the embodiments may be combined with each other.

A process for a gate structure in a method of manufacturing a semiconductor structure is prone to the necking phenomenon on sidewalls of the gate structure, which leads to a significant reduction in the performance of the semiconductor structure and thus seriously affects the product yield.

In the method of manufacturing a semiconductor structure and the semiconductor structure provided by the embodiments of the present disclosure, isolation sidewalls are formed on both sides of each gate structure to effectively control the morphology of sidewalls on both sides of the gate structure and protect the gate structure from the necking phenomenon, thereby effectively improving the product yield and the performance of the semiconductor structure.

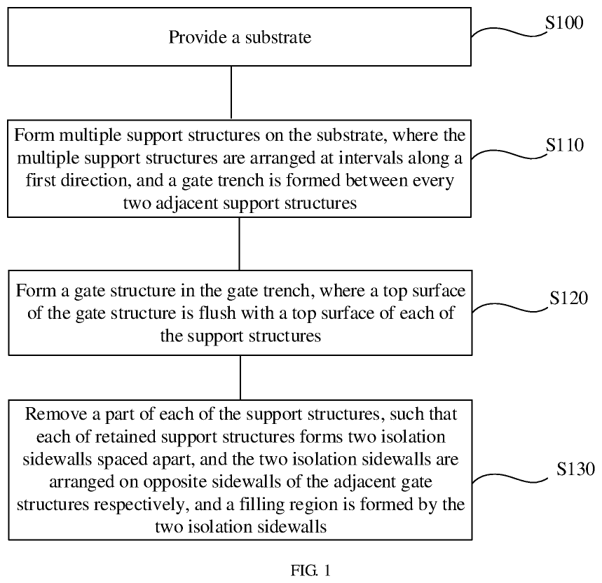

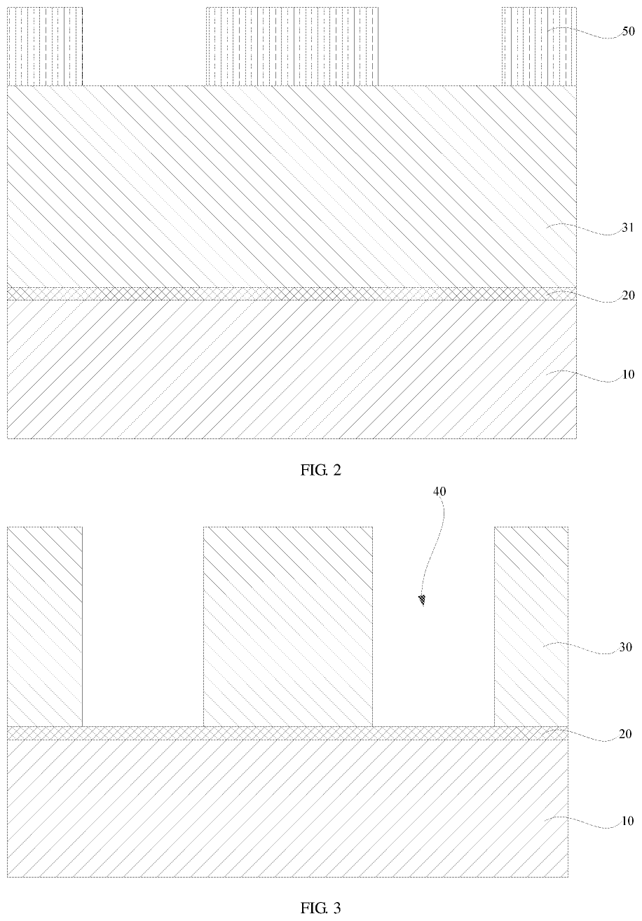

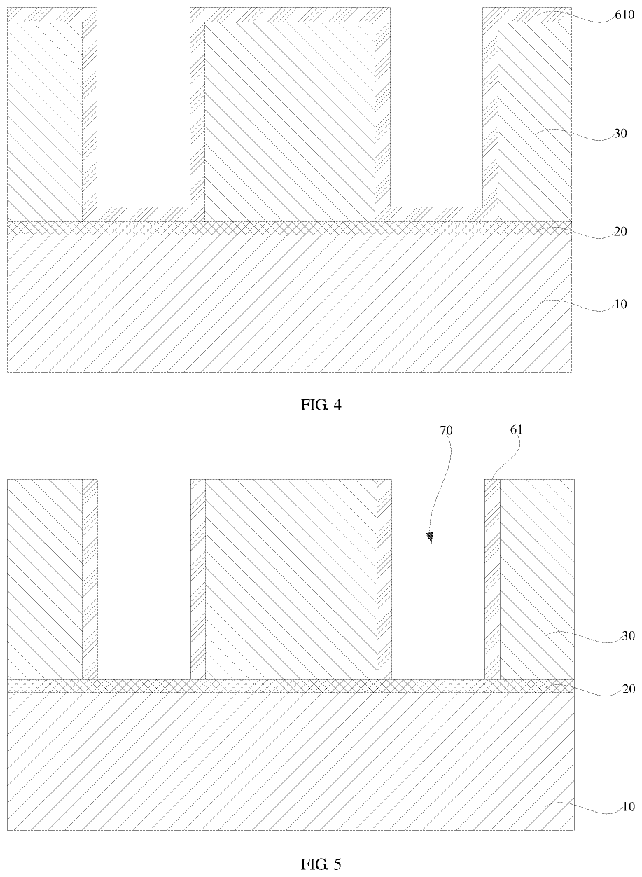

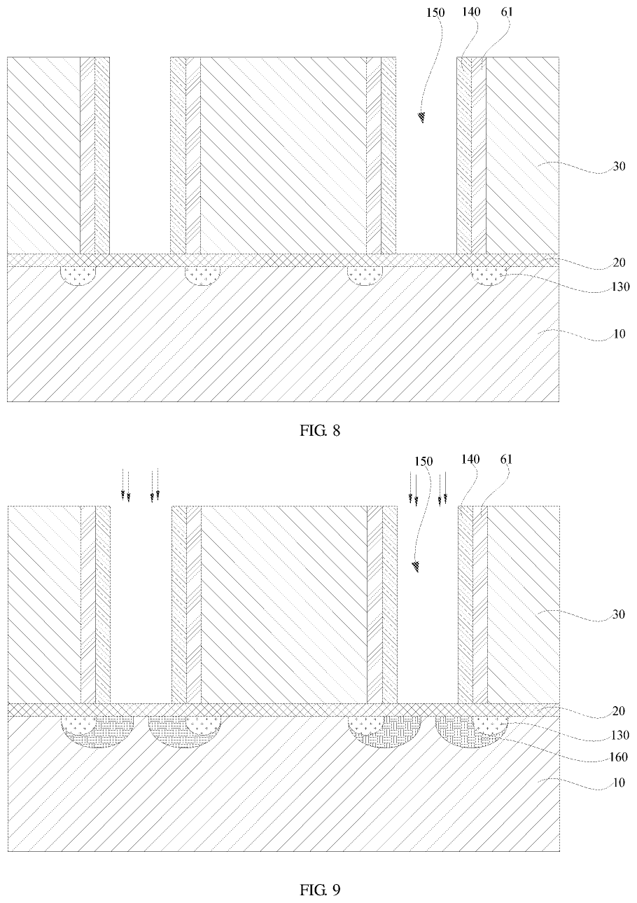

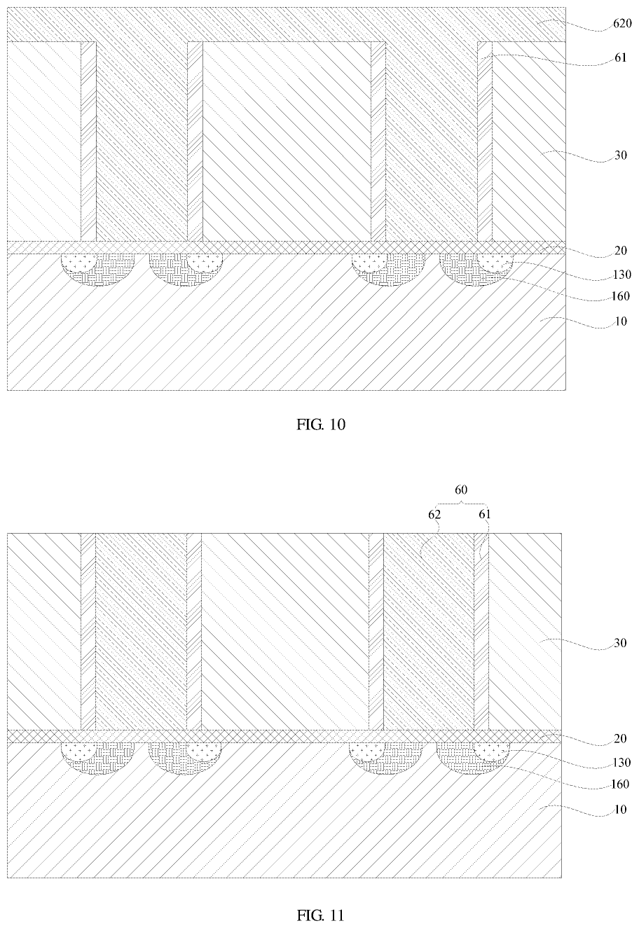

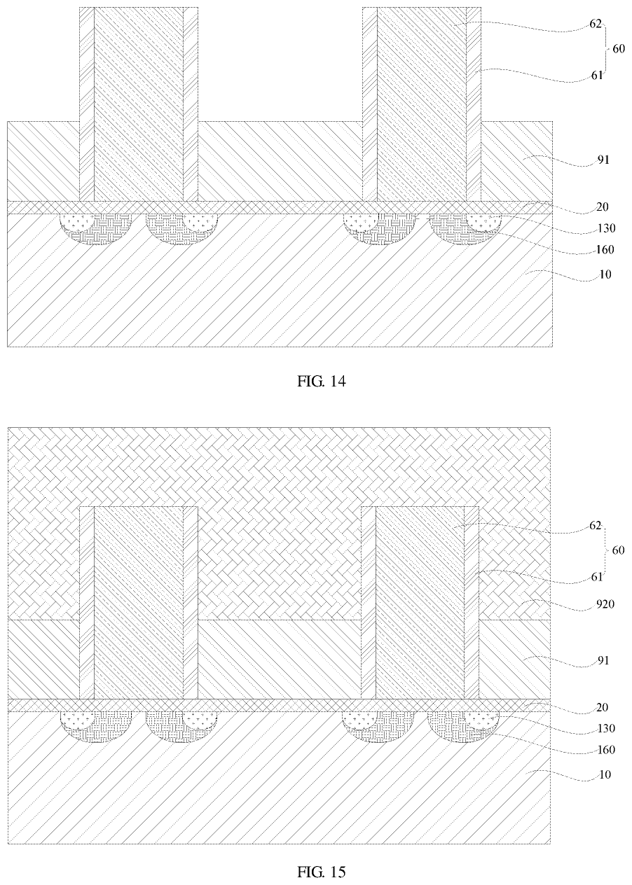

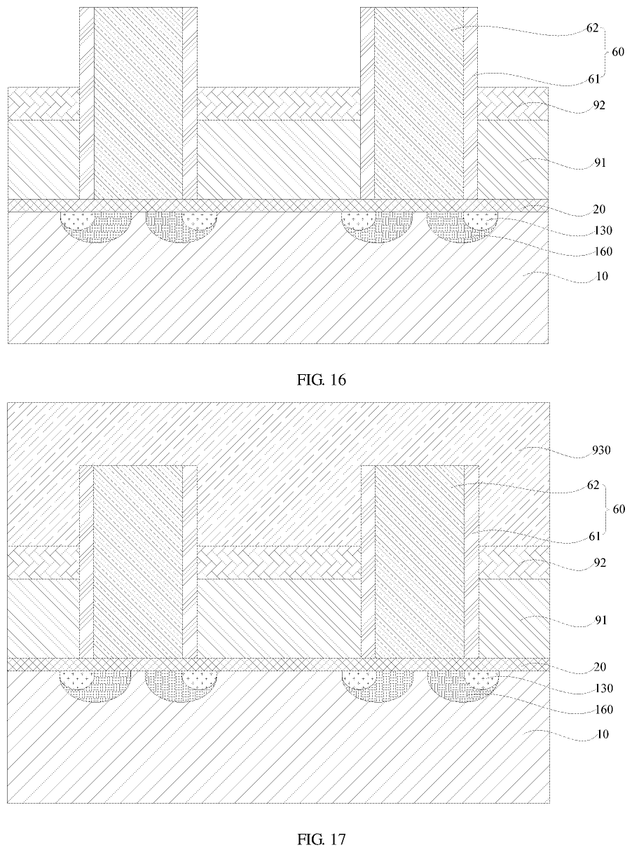

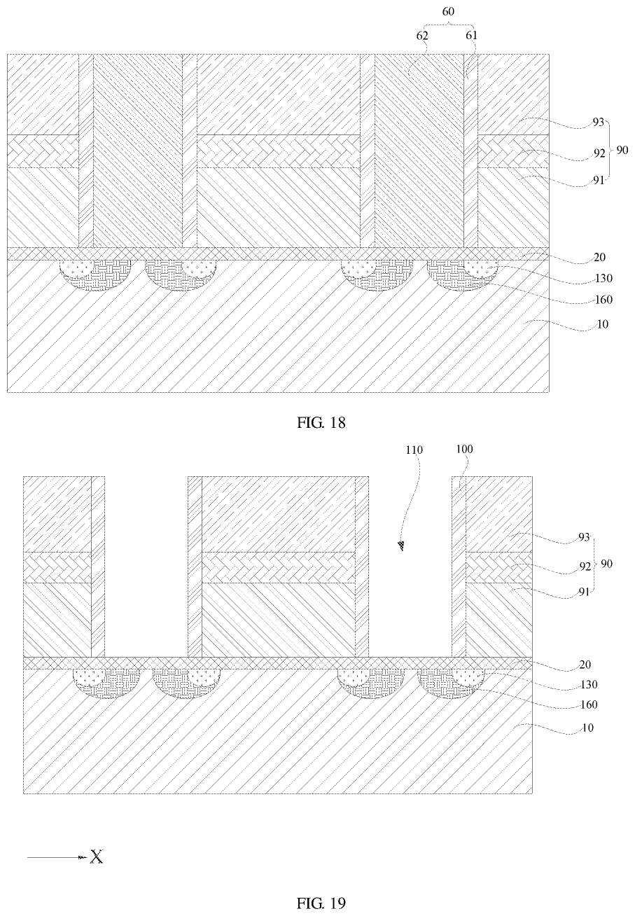

An exemplary embodiment of the present disclosure provides a method of manufacturing a semiconductor structure, as shown in FIG. 1. FIG. 1 is a flowchart of a method of manufacturing a semiconductor structure according to an exemplary embodiment. FIG. 2 to FIG. 20 are schematic diagrams of various stages of the method of manufacturing a semiconductor structure. The method of manufacturing a semiconductor structure is described below with reference to FIG. 2 to FIG. 20.

The semiconductor structure is not limited in this embodiment. The semiconductor structure is described below by taking a dynamic random access memory (DRAM) as an example, but this embodiment is not limited to this, and the semiconductor structure in this embodiment may also be other structures.

As shown in FIG. 1, a method of manufacturing a semiconductor structure provided by an exemplary embodiment of the present disclosure includes the following steps:

Step S100: Provide a substrate.

Step S110: Form multiple support structures on the substrate, where the multiple support structures are arranged at intervals along a first direction, and a gate trench is formed between every two adjacent support structures.

Step S120: Form a gate structure in the gate trench, where a top surface of the gate structure is flush with a top surface of each of the support structures.

Step S130: Remove a part of each of the support structures, such that each of the retained support structures forms two isolation sidewalls spaced apart, the two isolation sidewalls are arranged on opposite sidewalls of the adjacent gate structures respectively, and a filling region is formed by the two isolation sidewalls.

For example, as shown in FIG. 2, in step S100, the substrate 10 serves as a support component of a memory and is used to support other components provided thereon. The substrate 10 may be made of a semiconductor material. The semiconductor material may be one or more from the group consisting of silicon, germanium, silicon-germanium, and silicon oxide.

In this embodiment, the substrate 10 may be a semiconductor substrate having a shallow trench isolation structure, and the material of the semiconductor substrate may include silicon dioxide.

In step S110, as shown in FIG. 2, a dielectric layer 20 and a first initial sacrificial layer 31 stacked sequentially can be formed on the substrate 10 by atomic layer deposition, chemical vapor deposition, physical vapor deposition, spin coating, or a combination of the foregoing processes.

The dielectric layer 20 may be an oxide layer, or may be made of a high-k material. The use of the high-k material can improve the capacitance value per unit area of a capacitor, which helps increase the carrier mobility and improve the device performance. The high-k material may be one or more from the group consisting of ZrOₓ, HfOₓ, ZrTiOₓ, RuOₓ, and AlOₓ. The dielectric layer 20 made of the high-k material can be manufactured by atomic layer deposition (ALD), to ensure the film quality and thickness uniformity of the dielectric layer 20.

The first initial sacrificial layer 31 may be a Spin On Carbon (SOC) layer formed on the dielectric layer 20 through spin coating.

After that, as shown in FIG. 3, a part of the first initial sacrificial layer 31 is removed, and the retained first initial sacrificial layer 31 forms a first sacrificial layer 30. At the same time, a first groove 40 is formed by adjacent parts of the first sacrificial layer 30, and the bottom of the first groove 40 exposes a top surface of the dielectric layer 20.

In the process of removing a part of the first initial sacrificial layer 31, a second photeresist layer 50 may be formed on the first initial sacrificial layer 31 (as shown in FIG. 2), where the second photeresist layer 50 is a positive photoresist. A second mask pattern is formed on the second photeresist layer 50 through exposure or development etching. By using the second photeresist layer 50 with the second mask pattern as a mask plate, to remove the first sacrificial layer 30 not shielded by the second mask pattern, so as to form multiple first grooves 40 arranged at intervals.

The support structure 60 is formed in the first groove 40.

For example, in the process of forming the support structure 60 in the first groove 40, a sidewall protective layer 61 may be formed on sidewalls of the first groove 40 first, where top surface of the sidewall protective layer 61 is flush with top surface of the first sacrificial layer 30. In this case, a second groove 70 is formed by parts of the sidewall protective layer 61 on the two sidewalls in the first groove 40.

The sidewall protective layer 61 may be formed by using the following method:

First, an initial sidewall protective layer 610 is formed on inner walls of the first groove 40, where the initial sidewall protective layer 610 extends outside of the first groove 40 and covers the top surface of the first sacrificial layer 30. The initial sidewall protective layer 610 may be a silicon nitride layer deposited through atomic layer deposition. Then, the initial sidewall protective layer 610 at the bottom of the first groove 40 and on the top surface of the first sacrificial layer 30 may be removed through dry etching, such that the retained initial sidewall protective layer 610 forms the sidewall protective layer 61.

Then, a second initial sacrificial layer 620 may be formed on inner walls of the second groove 70 through atomic layer deposition, chemical vapor deposition, and physical vapor deposition, where the second initial sacrificial layer 620 extends outside of the second groove 70 and covers the top surface of the first sacrificial layer 30. The second initial sacrificial layer 620 may include an oxide layer.

A part of the second initial sacrificial layer 620 may be removed through plasma etching to expose the top surface of the first sacrificial layer 30, and the retained second initial sacrificial layer 620 forms a second sacrificial layer 62. The second sacrificial layer 62 and the sidewall protective layer 61 on both sides form the support structure 60. The multiple support structures 60 are arranged at intervals along the first direction, where the first direction is direction X shown in FIG. 19, and a gate trench 80 is formed between every two adjacent support structures 60.

As shown in FIG. 12, the retained first sacrificial layer 30 is removed through a dry etching process, such that a gate trench 80 is formed between every two adjacent support structures 60. In this embodiment, the first sacrificial layer 30 may be removed by introducing an etching gas such as oxygen. That is, oxygen is introduced to remove the SOC layer.

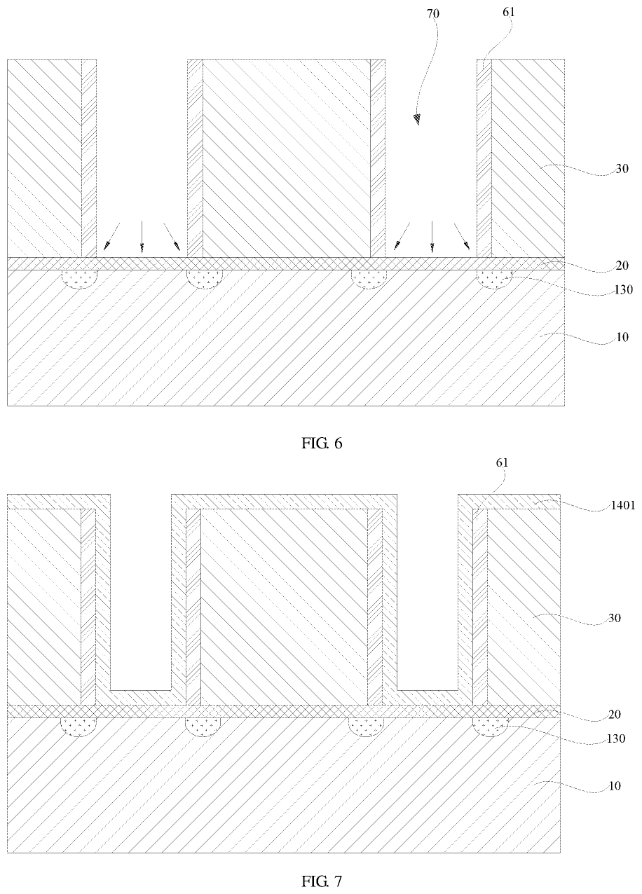

In some embodiments, as shown in FIG. 6 to FIG. 9, after the second groove 70 are formed, first ion implantation may further be performed at the bottom of the second groove 70, to form a lightly-doped region 130 in the substrate 10. The lightly-doped region 130 may be formed at an intersection between the substrate 10 and an extension line along a direction from the bottom of the second groove 70 towards the substrate 10, and may be arranged in two opposite regions at the bottom of the second groove 70. Moreover, a gap between the opposite parts of the sidewall protective layer 61 on the sidewalls of the second groove 70 may define a forming profile of the lightly-doped region 130. For example, along a longitudinal section perpendicular to the top surface of the substrate 10, a shape of a longitudinal section of the lightly-doped region 130 may include a square segment connected to the top surface of the substrate 10 and a dome segment connected to a lower end of the square segment.

A first oxide layer 140 is formed, through atomic layer deposition, on each inner wall of the second groove 70 where the lightly-doped region 130 is formed. A third groove 150 is formed by the first oxide layer 140 in the second groove 70. Then, a second initial oxide layer is filled in the third groove 150, where the second initial oxide layer extends outside of the third groove 150 and covers the top surface of the first sacrificial layer 30. The first oxide layer 140 and the second initial oxide layer may be made of the same material or different materials. In this embodiment, the first oxide layer 140 and the second initial oxide layer are made of the same material, and together form the second initial sacrificial layer 620.

The process of forming the first oxide layer 140 may be as follows: a first initial oxide layer 1401 is formed on the inner walls of the second groove 70, where the first initial oxide layer 1401 extends outside of the second groove 70 and covers the top surface of the first sacrificial layer 30 and the top surface of the sidewall protective layer 61. Then, the first initial oxide layer 1401 at the bottom of the second groove 70 and on the top of the first sacrificial layer 30 and the sidewall protective layer 61 through dry etching, to expose the top surface of the dielectric layer 20 as well as the top surface of the first sacrificial layer 30 and sidewall protective layer 61, such that the retained first initial oxide layer 1401 forms the first oxide layer 140.

After the third groove 150 is formed, second ion implantation is performed at the bottom of the third groove 150, so as to form a source-drain region 160 at the bottom of the third groove 150. The source-drain region 160 may be formed at an intersection between the substrate 10 and an extension line along a direction from the bottom of the third groove 150 towards the substrate 10, and may be arranged in two opposite regions at the bottom of the second groove 70. Along the longitudinal section perpendicular to the top surface of the substrate 10, a longitudinal sectional area of the source-drain region 160 is larger than a longitudinal sectional area of the lightly-doped region 130; meanwhile, a projection region of the source-drain region 160 on a section perpendicular to the top surface of the substrate 10 partially overlaps with a projection region of the lightly-doped region 130 on a section perpendicular to the top surface of the substrate 10.

In step S120, as shown in FIG. 12, the gate structure 90 is formed in the gate trench 80, where a top surface of the gate structure 90 is flush with the top surface of each of the support structures 60.

In this embodiment, the gate structure 90 includes a polysilicon layer 91, a conductive layer 92, and an isolation layer 93 that are sequentially deposited in the gate trench 80, a top surface of the polysilicon layer 91 is lower than the top surface of the support structure 60, a top surface of the conductive layer 92 is lower than the top surface of the support structure 60, and a top surface of the isolation layer 93 is flush with the top surface of the support structure 60.

The polysilicon layer 91 may be formed by using the following method:

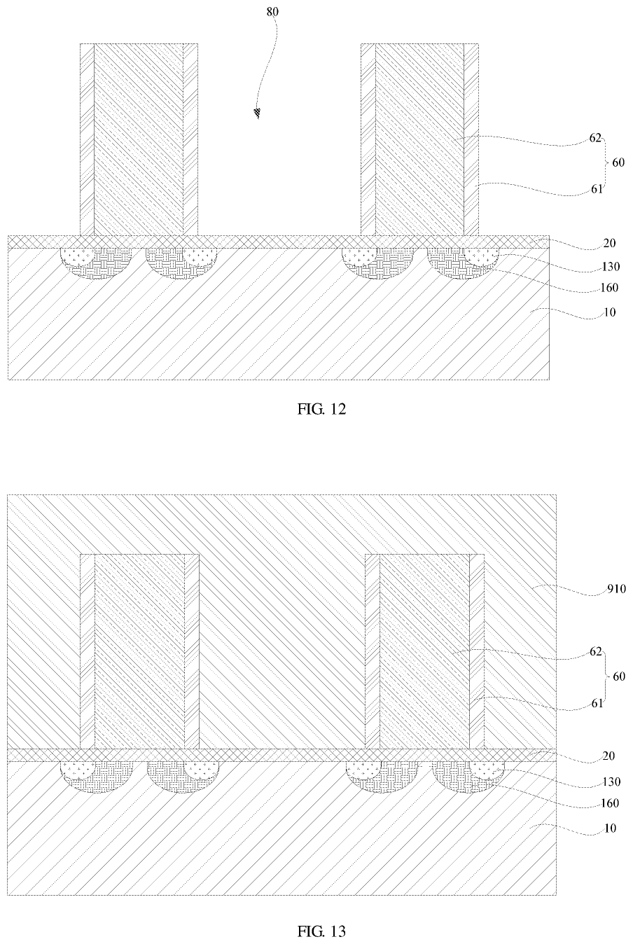

As shown in FIG. 13 to FIG. 18, an initial polysilicon layer 910 may be deposited in the gate trench 80 through atomic layer deposition, chemical vapor deposition or physical vapor deposition, then a part of the initial polysilicon layer 910 is removed through etching back, such that a top surface of the initial polysilicon layer 910 is lower than the top surface of each of the support structures 60, and the retained initial polysilicon layer 910 forms the polysilicon layer 91.

The conductive layer 92 is formed by using the following method:

An initial conductive layer 920 is deposited on the polysilicon layer 91 in the gate trench 80 through atomic layer deposition, chemical vapor deposition or physical vapor deposition, and a part of the initial conductive layer 920 is removed through etching back, such that a top surface of the initial conductive layer 920 is lower than the top surface of each of the support structures 60, and the retained initial conductive layer 920 forms the conductive layer 92. In this embodiment, the conductive layer 92 includes at least one of a titanium nitride layer and a tungsten layer.

Then an initial isolation layer 930 is deposited on the conductive layer 92 through atomic layer deposition, and a part of the initial isolation layer 930 is removed through etching back, until the top surfaces of the support structures 60 are exposed, and the retained initial isolation layer 930 forms the isolation layer 93. In this embodiment, the isolation layer 93 may be made of silicon nitride.

In step S130, as shown in FIG. 19, a part of each of the support structures 60 is removed, and each of the retained support structures 60 forms two isolation sidewalls 100 spaced apart. The two isolation sidewalls 100 are arranged on opposite sidewalls of the adjacent gate structures 90 respectively, and a filling region 110 is formed by the two isolation sidewall.

In the process of removing a part of each of the support structures 60, a third photoresist layer may be formed on the top surface of the isolation layer 93 and the top surface of each of the support structures 60. A third mask pattern is formed on the third photoresist layer through exposure or development etching. A part of each of the support structures 60 is etched by using the third photoresist layer with the third mask pattern as a mask plate, and a part of each of the support structures 60 is removed, until the top surface of the dielectric layer 20 is exposed. In this embodiment, the removed part of each of the support structures 60 is the second sacrificial layer 62, and each of the retained support structures 60 forms the sidewall protective layer 61, that is, the sidewall protective layer 61 forms the isolation sidewalls 100. Each of the isolation sidewalls 100 may further include the sidewall protective layer 61 and a part of the second sacrificial layer 62. Alternatively, with reference to direction X in FIG. 19, each of the isolation sidewalls may include a part of the sidewall protective layer 61 in the thickness direction.

In this embodiment, the isolation sidewalls are formed on both sides of each gate structure to effectively control the morphology of sidewalls on both sides of the gate structure and protect the gate structure from the necking phenomenon, thereby effectively improving the product yield and the performance of the semiconductor structure.

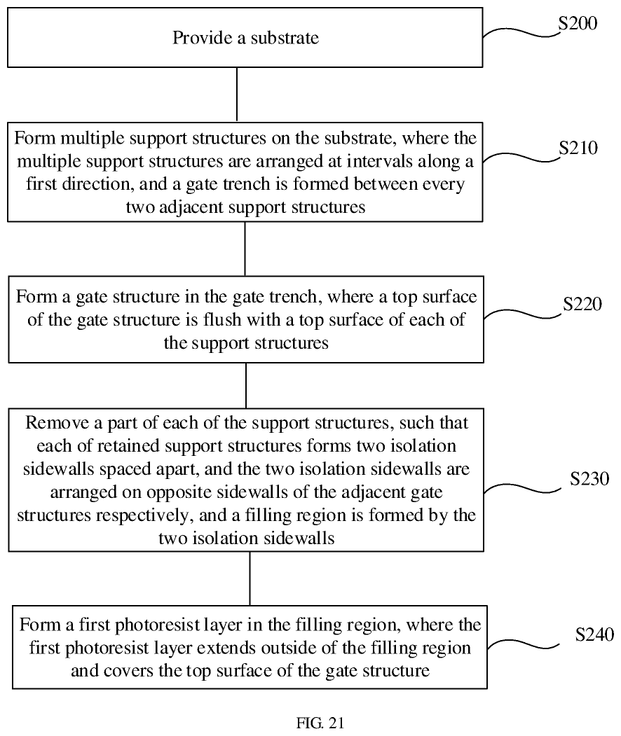

According to an exemplary embodiment, as shown in FIG. 21, FIG. 21 shows a flowchart of a method of manufacturing a semiconductor structure according to this embodiment. The method of manufacturing a semiconductor structure includes following steps:

Step S200: Provide a substrate.

Step S210: Form multiple support structures on the substrate, where the multiple support structures are arranged at intervals along a first direction, and a gate trench is formed between every two adjacent support structures.

Step S220: Form a gate structure in the gate trench, where a top surface of the gate structure is flush with top surface of each of the support structures.

Step S230: Remove a part of each of the support structures, such that each of the retained support structures forms two isolation sidewalls spaced apart, the two isolation sidewalls are arranged on opposite sidewalls of the adjacent gate structures respectively, and a filling region is formed by the two isolation sidewalls.

Step S240: Form a first photoresist layer in the filling region, where the first photoresist layer extends outside of the filling region and covers the top surface of the gate structure.

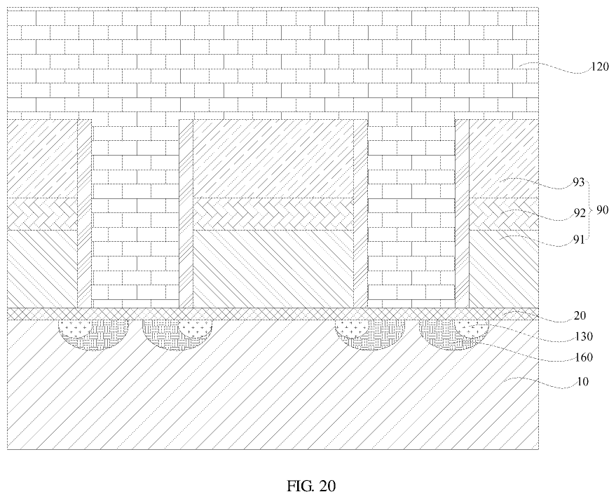

For example, as shown in FIG. 20, in step S240, a first photoresist layer 120 is filled in the filling region 110, and a top surface of the first photoresist layer 120 covers the top surface of the gate structure 90 and exceeds the top surface of the gate structure 90 by a predetermined height. Then, subsequent array region processes are performed.

In this embodiment, step S200 to step S230 in this embodiment are implemented in the same manner as step S100 to step S130 in the foregoing embodiment, and this embodiment will not be described in detail again herein.

As shown in FIG. 20, an embodiment of the present disclosure further provides a semiconductor structure. The semiconductor structure is manufactured by the method of manufacturing a semiconductor structure in the foregoing embodiment. The semiconductor structure in this embodiment includes a substrate 10, a dielectric layer 20 disposed on the substrate 10, and gate structures 90 arranged at intervals on the dielectric layer 20. Isolation sidewalls 100 are provided on both sides of each of the gate structures 90. In addition, a source-drain region 160 is provided in the substrate 10, where the source-drain region 160 may be formed at an intersection between the substrate 10 and an extension line along a direction from the bottom of each of the isolation sidewalls 100 towards the substrate 10.

The isolation sidewalls are formed on both sides of each gate structure to effectively control the morphology of sidewalls on both sides of the gate structure and protect the gate structure from the necking phenomenon, thereby effectively improving the product yield and the performance of the semiconductor structure.

The embodiments or implementations of this specification are described in a progressive manner, and each embodiment focuses on differences from other embodiments. The same or similar parts between the embodiments may refer to each other.

In the description of the specification, the description with reference to terms such as “an embodiment”, “an illustrative embodiment”, “some implementations”, “an illustrative implementation” and “an example” means that the specific feature, structure, material or feature described in combination with the implementation(s) or example(s) is included in at least one implementation or example of the present disclosure.

In this specification, the schematic expression of the above terms does not necessarily refer to the same implementation or example. Moreover, the described specific feature, structure, material or characteristic may be combined in an appropriate manner in any one or more implementations or examples.

It should be noted that in the description of the present disclosure, the terms such as “center”, “top”, “bottom”, “left”, “right”, “vertical”, “horizontal”, “inner” and “outer” indicate the orientation or position relationships based on the drawings. These terms are merely intended to facilitate description of the present disclosure and simplify the description, rather than to indicate or imply that the mentioned device or element must have a specific orientation and must be constructed and operated in a specific orientation. Therefore, these terms should not be construed as a limitation to the present disclosure.

It can be understood that the terms such as “first” and “second” used in the present disclosure can be used to describe various structures, but these structures are not limited by these terms. Instead, these terms are merely intended to distinguish one element from another.

The same elements in one or more drawings are denoted by similar reference numerals. For the sake of clarity, various parts in the drawings are not drawn to scale. In addition, some well-known parts may not be shown. For the sake of brevity, the structure obtained by implementing multiple steps may be shown in one figure. In order to make the understanding of the present disclosure more clearly, many specific details of the present disclosure, such as the structure, material, size, processing process and technology of the device, are described below. However, as those skilled in the art can understand, the present disclosure may not be implemented according to these specific details.

Finally, it should be noted that the above embodiments are merely intended to explain the technical solutions of the present disclosure, rather than to limit the present disclosure. Although the present disclosure is described in detail with reference to the above embodiments, those skilled in the art should understand that they may still modify the technical solutions described in the above embodiments, or make equivalent substitutions of some or all of the technical features recorded therein, without deviating the essence of the corresponding technical solutions from the scope of the technical solutions of the embodiments of the present disclosure.

### INDUSTRIAL APPLICABILITY

In the method of manufacturing a semiconductor structure and the semiconductor structure provided by the embodiments of the present disclosure, isolation sidewalls are provided on both sides of each gate structure to effectively control the morphology of sidewalls on both sides of the gate structure and protect the gate structure from the necking phenomenon, thereby effectively improving the product yield and the performance of the semiconductor structure.

1. A method of manufacturing a semiconductor structure, comprising:
providing a substrate;
forming multiple support structures on the substrate, wherein the multiple support structures are arranged at intervals along a first direction, and a gate trench is formed between every two adjacent support structures;
forming a gate structure in the gate trench, wherein a top surface of the gate structure is flush with a top surface of each of the support structures; and
removing a part of each of the support structures, such that each of retained support structures forms two isolation sidewalls spaced apart, the two isolation sidewalls are arranged on opposite sidewalls of the adjacent gate structures respectively, and a filling region is formed by the two isolation sidewalls.

2. The method of manufacturing a semiconductor structure according to claim 1, wherein the forming multiple support structures on the substrate comprises:
forming a first initial sacrificial layer on the substrate;
removing a part of the first initial sacrificial layer, such that a retained first initial sacrificial layer forms a first sacrificial layer, a first groove is formed by every two adjacent parts of the first sacrificial layer, and the first groove exposes a top surface of the substrate;
forming the support structure in the first groove; and
removing the retained first sacrificial layer.

3. The method of manufacturing a semiconductor structure according to claim 2, further comprising:
forming a dielectric layer on the substrate; and
forming the first initial sacrificial layer on the dielectric layer.

4. The method of manufacturing a semiconductor structure according to claim 2, wherein the forming the support structure in the first groove comprises:
forming a sidewall protective layer on sidewalls of the first groove, wherein a second groove is formed by the sidewall protective layer located in the first groove;
forming a second initial sacrificial layer on inner walls of the second groove, wherein the second initial sacrificial layer extends outside of the second groove and covers a top surface of the first sacrificial layer; and
removing a part of the second initial sacrificial layer to expose the top surface of the first sacrificial layer, such that the retained second initial sacrificial layer forms a second sacrificial layer, wherein the sidewall protective layer forms the isolation sidewalls, the second groove forms the filling region, and the second sacrificial layer and the sidewall protective layer on both sides form the support structure.

5. The method of manufacturing a semiconductor structure according to claim 4, wherein the forming a sidewall protective layer on sidewalls of the first groove comprises:
forming an initial sidewall protective layer on inner walls of the first groove, wherein the initial sidewall protective layer extends outside of the first groove and covers the top surface of the first sacrificial layer; and
removing the initial sidewall protective layer at a bottom of the first groove and on the top surface of the first sacrificial layer, such that a retained initial sidewall protective layer forms the sidewall protective layer.

6. The method of manufacturing a semiconductor structure according to claim 5, wherein the forming a sidewall protective layer on sidewalls of the first groove, wherein a second groove is formed by the sidewall protective layer located in the first groove comprises:
performing first ion implantation at a bottom of the second groove, to form a lightly-doped region in the substrate, wherein a gap between the opposite parts of the sidewall protective layer on sidewalls of the second groove defines a forming profile of the lightly-doped region.

7. The method of manufacturing a semiconductor structure according to claim 6, further comprising:
forming a first oxide layer on inner walls of the second groove, wherein a third groove is formed by the first oxide layer in the second groove; and
forming a second initial oxide layer in the third groove, wherein the second initial oxide layer extends outside of the third groove and covers the top surface of the first sacrificial layer, and the first oxide layer and the second initial oxide layer form the second initial sacrificial layer.

8. The method of manufacturing a semiconductor structure according to claim 7, wherein the forming a first oxide layer on inner walls of the second groove comprises:
forming a first initial oxide layer on the inner walls of the second groove, wherein the first initial oxide layer extends outside of the second groove and covers the top surface of the first sacrificial layer and a top surface of the sidewall protective layer; and
removing the first initial oxide layer at the bottom of the second groove, on a top of the first sacrificial layer and on a top of the sidewall protective layer, such that a retained first initial oxide layer forms the first oxide layer.

9. The method of manufacturing a semiconductor structure according to claim 8, wherein the forming a first oxide layer on inner walls of the second groove, wherein a third groove is formed by the first oxide layer in the second groove comprises:
performing second ion implantation at a bottom of the third groove, to form a source-drain region.

10. The method of manufacturing a semiconductor structure according to claim 9, wherein along a longitudinal section perpendicular to the top surface of the substrate, a longitudinal sectional area of the source-drain region is larger than a longitudinal sectional area of the lightly-doped region.

11. The method of manufacturing a semiconductor structure according to claim 1, wherein the forming a gate structure in the gate trench comprises:
forming a polysilicon layer in the gate trench, wherein a top surface of the polysilicon layer is lower than the top surface of each of the support structures;
forming a conductive layer on the polysilicon layer, wherein a top surface of the conductive layer is lower than the top surface of each of the support structures; and
forming an isolation layer on the conductive layer, wherein a top surface of the isolation layer is flush with the top surface of each of the support structures, and the polysilicon layer, the conductive layer and the isolation layer form the gate structure.

12. The method of manufacturing a semiconductor structure according to claim 11, wherein the forming a polysilicon layer in the gate trench comprises:
forming an initial polysilicon layer in the gate trench; and
removing a part of the initial polysilicon layer, such that a retained initial polysilicon layer forms the polysilicon layer.

13. The method of manufacturing a semiconductor structure according to claim 11, wherein the forming a conductive layer on the polysilicon layer comprises:
forming an initial conductive layer on the polysilicon layer; and
removing a part of the initial conductive layer, such that a retained initial conductive layer forms the conductive layer.

14. The method of manufacturing a semiconductor structure according to claim 11, wherein the forming an isolation layer on the conductive layer comprises:
forming an initial isolation layer on the conductive layer; and
removing a part of the initial isolation layer to expose the top surface of each of the support structures, such that the retained initial isolation layer forms the isolation layer.

15. The method of manufacturing a semiconductor structure according to claim 1, further comprising:
forming a first photoresist layer in the filling region, wherein the first photoresist layer extends outside of the filling region and covers the top surface of the gate structure.

16. A semiconductor structure, comprising a substrate, and gate structures arranged at intervals on the substrate, wherein isolation sidewalls are arranged on opposite sidewalls of every two adjacent gate structures;
a filling region is formed by two opposite isolation sidewalls spaced apart; and
a top surface of each of the gate structures is flush with a top surface of each of the isolation sidewalls.

17. The semiconductor structure according to claim 16, further comprising a first photoresist layer, wherein the first photoresist layer fills the filling region, extends outside of the filling region, and covers the top surface of each of the gate structures.

18. The semiconductor structure according to claim 16, further comprising a dielectric layer provided between the substrate and the gate structures.

19. The semiconductor structure according to claim 16, wherein each of the gate structures comprises a polysilicon layer, a conductive layer, and an isolation layer in sequence, a top surface of the isolation layer being flush with the top surface of each of the isolation sidewalls.

20. The semiconductor structure according to claim 17, wherein a lightly-doped region and a source-drain region are provided in the substrate, the lightly-doped region and the source-drain region are arranged below two opposite isolation sidewalls that are spaced apart; and along a longitudinal section perpendicular to a top surface of the substrate, a longitudinal sectional area of the source-drain region is larger than a longitudinal sectional area of the lightly-doped region.
